(19) United States
(12) Patent Application Publication
(10) Pub. No.: US 2025/0241177 A1
(43) Pub. Date: Jul. 24, 2025

(54) DISPLAY DEVICE AND MANUFACTURING METHOD FOR THE SAME

(71) Applicant: Samsung Display Co., LTD., Yongin-si (KR)

(72) Inventors: WOOSUK JUNG, Yongin-si (KR); JONGWOO KIM, Yongin-si (KR); SOYOUNG OH, Yongin-si (KR); HYUNSUP YOON, Yongin-si (KR); JAEHEUNG HA, Yongin-si (KR)

(21) Appl. No.: 19/015,090

(22) Filed: Jan. 9, 2025

(30) Foreign Application Priority Data
Jan. 19, 2024 (KR) 10-2024-0008781

(51) Int. Cl. H10K 59/80; H10K 59/12; H10K 59/122

(52) U.S. Cl. CPC H10K 59/873; H10K 59/1201; H10K 59/122

(57) ABSTRACT

A display device includes an encapsulation layer. The encapsulation layer includes a first inorganic encapsulation film, an organic encapsulation film disposed on the first inorganic encapsulation film, and a second inorganic encapsulation film disposed on the organic encapsulation film. The second inorganic encapsulation film includes a first sub-inorganic encapsulation layer and a second sub-inorganic encapsulation layer that is disposed on the first sub-inorganic encapsulation layer and that includes a material identical to a material of the first sub-inorganic encapsulation layer, and a density of the first sub-inorganic encapsulation layer and a density of the second sub-inorganic encapsulation layer are different from each other. A sum of a thickness of the first inorganic encapsulation film and a thickness of the second inorganic encapsulation film is 1 micrometer or less.

This application claims priority to Korean Patent Application No. 10-2024-0008781, filed on Jan. 19, 2024, and all the benefits accruing therefrom under 35 U.S.C. § 119, the content of which in its entirety is herein incorporated by reference.

### BACKGROUND

### 1. Field

Embodiments of the disclosure described herein relate to a display device and a manufacturing method thereof, and more particularly, relate to a display device including an inorganic encapsulation film and a method for manufacturing the display device.

### 2. Description of the Related Art

Various types of display devices are used to provide image information, and an emissive display device using an organic luminescent material or a quantum-dot luminescent material is being developed. The emissive display device includes light-emitting elements. The light-emitting elements are vulnerable to external environments such as oxygen and moisture, and therefore various technologies for sealing the light-emitting elements are desired. Among the various technologies, a technology for blocking an infiltration path of air and moisture by disposing an encapsulation layer on light-emitting elements is being developed. The encapsulation layer may include a structure in which an inorganic film including an inorganic material and an organic film including an organic material are alternately stacked.

### SUMMARY

Embodiments of the disclosure provide a display device including an encapsulation layer having a relatively small thickness and a relatively low water vapor transmission rate and a method for manufacturing the display device.

In an embodiment of the disclosure, a display device includes a display panel. The display panel includes a display element layer and an encapsulation layer disposed on the display element layer, and the display element layer includes a pixel defining layer defining a pixel opening therein and a light-emitting element. The encapsulation layer includes a first inorganic encapsulation film, an organic encapsulation film disposed on the first inorganic encapsulation film, and a second inorganic encapsulation film disposed on the organic encapsulation film, and the second inorganic encapsulation film includes a first sub-inorganic encapsulation layer and a second sub-inorganic encapsulation layer that is disposed on the first sub-inorganic encapsulation layer and that includes a material identical to a material of the first sub-inorganic encapsulation layer. A density of the first sub-inorganic encapsulation layer and a density of the second sub-inorganic encapsulation layer are different from each other, and the sum of a thickness of the first inorganic encapsulation film and a thickness of the second inorganic encapsulation film is 1 micrometer or less.

In an embodiment, the density of the second sub-inorganic encapsulation layer may be higher than the density of the first sub-inorganic encapsulation layer.

In an embodiment, the first sub-inorganic encapsulation layer and the second sub-inorganic encapsulation layer may include silicon nitride.

In an embodiment, the thickness of the second inorganic encapsulation film may be 0.5 micrometer or less.

In an embodiment, the thickness of the first inorganic encapsulation film may be 0.5 micrometer or less.

In an embodiment, the second inorganic encapsulation film may further include a third sub-inorganic encapsulation layer disposed on the second sub-inorganic encapsulation layer and a fourth sub-inorganic encapsulation layer disposed on the third sub-inorganic encapsulation layer. A material of each of the third sub-inorganic encapsulation layer and the fourth sub-inorganic encapsulation layer may be identical to the material of the first sub-inorganic encapsulation layer. The density of the second sub-inorganic encapsulation layer and a density of the third sub-inorganic encapsulation layer may be different from each other, and the density of the third sub-inorganic encapsulation layer and a density of the fourth sub-inorganic encapsulation layer may be different from each other.

In an embodiment, the first inorganic encapsulation film may include a first sub-inorganic encapsulation layer and a second sub-inorganic encapsulation layer that is disposed on the first sub-inorganic encapsulation layer of the first inorganic encapsulation film and that includes a material identical to a material of the first sub-inorganic encapsulation layer of the first inorganic encapsulation film. A density of the first sub-inorganic encapsulation layer of the first inorganic encapsulation film and a density of the second sub-inorganic encapsulation layer of the first inorganic encapsulation film may be different from each other.

In an embodiment, the encapsulation layer may have a water vapor transmission rate of less than or equal to 1.5×10⁻⁴ grams per square meter per 24 hours (g/m² day).

In an embodiment, the light-emitting element may include a first electrode, an emissive layer disposed on the first electrode, and a second electrode disposed on the emissive layer.

In an embodiment, the display device may further include an active area that displays an image, and the active area may include a flat area and at least one curved area bent from the flat area.

In an embodiment, the display device may further include a base layer that is disposed under the display element layer and that includes a silicon wafer and a color filter layer disposed on the encapsulation layer.

In an embodiment, the light-emitting element may include a first electrode, a light-emitting part including a first light-emitting stack disposed on the first electrode, a charge generation layer disposed on the first light-emitting stack, and a second light-emitting stack disposed on the charge generation layer, and a second electrode disposed on the light-emitting part.

In an embodiment, the display device may further include a folding area folded about a virtual axis that extends in one direction, and a first non-folding area and a second non-folding area disposed with the folding area therebetween.

In an embodiment of the disclosure, a method for manufacturing a display device includes forming a first inorganic encapsulation film on a display element layer including a pixel defining layer having a pixel opening defined therein and a light-emitting element, forming an organic encapsulation film on the first inorganic encapsulation film, and forming a second inorganic encapsulation film on the organic encapsulation film. The forming the second inorganic encapsulation film includes depositing a first sub-inorganic encapsulation layer and depositing a second sub-inorganic encapsulation layer on the first sub-inorganic encapsulation layer. A material of the first sub-inorganic encapsulation layer and a material of the second sub-inorganic encapsulation layer are identical to each other, and density of the first sub-inorganic encapsulation layer and a density of the second sub-inorganic encapsulation layer are different from each other, and the sum of a thickness of the first inorganic encapsulation film and a thickness of the second inorganic encapsulation film is 1 micrometer or less.

In an embodiment, the depositing the first sub-inorganic encapsulation layer and the depositing the second sub-inorganic encapsulation layer may be controlled with different process parameters.

In an embodiment, the forming the second inorganic encapsulation film may further include depositing a third sub-inorganic encapsulation layer on the second sub-inorganic encapsulation layer and depositing a fourth sub-inorganic encapsulation layer on the third sub-inorganic encapsulation layer. A material of each of the third sub-inorganic encapsulation layer and the fourth sub-inorganic encapsulation layer may be identical to the material of the first sub-inorganic encapsulation layer. The density of the second sub-inorganic encapsulation layer and a density of the third sub-inorganic encapsulation layer may be different from each other, and the density of the third sub-inorganic encapsulation layer and a density of the fourth sub-inorganic encapsulation layer may be different from each other.

In an embodiment, the forming the first inorganic encapsulation film may include depositing a first sub-inorganic encapsulation layer of the first inorganic encapsulation film on the display element layer and depositing a second sub-inorganic encapsulation layer of the first inorganic encapsulation film on the first sub-inorganic encapsulation layer of the first inorganic encapsulation film. A material of the first sub-inorganic encapsulation layer of the first inorganic encapsulation film and a material of the second sub-inorganic encapsulation layer of the first inorganic encapsulation film may identical to each other, and a density of the first sub-inorganic encapsulation layer of the first inorganic encapsulation film and a density of the second sub-inorganic encapsulation layer of the first inorganic encapsulation film may be different from each other.

In an embodiment, the first sub-inorganic encapsulation layer and the second sub-inorganic encapsulation layer may include silicon nitride.

In an embodiment, the second inorganic encapsulation film may have a thickness of 0.5 micrometer or less.

In an embodiment, the density of the second sub-inorganic encapsulation layer may be higher than the density of the first sub-inorganic encapsulation layer.

### BRIEF DESCRIPTION OF THE DRAWINGS

The above and other embodiments, advantages and features of the disclosure will become apparent by describing in detail embodiments thereof with reference to the accompanying drawings.

FIG. 1 is a perspective view illustrating an embodiment of a display device according to the disclosure.

FIG. 2 is a cross-sectional view illustrating an embodiment of a portion corresponding to line I-I′ of FIG. 1.

FIG. 3 is an enlarged cross-sectional view illustrating area XX′ in FIG. 2.

FIG. 4A is a cross-sectional view illustrating a portion of a display panel according to the disclosure.

FIGS. 4B and 4C are flowcharts illustrating an embodiment of a method of manufacturing the display device according to the disclosure.

FIG. 5A is a cross-sectional view illustrating an embodiment of a portion of the display panel according to the disclosure.

FIG. 5B is a flowchart illustrating an embodiment of a method of manufacturing the display device according to the disclosure.

FIG. 6A is a cross-sectional view illustrating an embodiment of a portion of the display panel according to the disclosure.

FIG. 6B is a flowchart illustrating an embodiment of a method of manufacturing the display device according to the disclosure.

FIG. 7 is a cross-sectional view illustrating an embodiment of a portion of the display panel according to the disclosure.

FIG. 8 is a cross-sectional view of an embodiment of a display device according to the disclosure.

FIGS. 9A and 9B are enlarged cross-sectional views of an embodiment of portions of light-emitting elements according to the disclosure.

FIG. 10 is a perspective view illustrating an embodiment of a display device according to the disclosure.

FIGS. 11 and 12 are perspective views of an embodiment of the folded display device according to the disclosure.

### DETAILED DESCRIPTION

In this specification, when it is mentioned that a component (or, an area, a layer, a part, etc.) is referred to as being “on”, “connected to” or “coupled to” another component, this means that the component may be directly on, connected to, or coupled to the other component or a third component may be therebetween.

Identical reference numerals refer to identical components. Additionally, in the drawings, the thicknesses, proportions, and dimensions of components are exaggerated for effective description. As used herein, the term “and/or” includes all of one or more combinations defined by related components.

Terms such as first, second, and the like may be used to describe various components, but the components should not be limited by the terms. The terms may be used only for distinguishing one component from other components. For example, without departing the scope of the disclosure, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship of components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Unless otherwise defined, all terms used herein, including technical or scientific terms, have the same meanings as those generally understood by those skilled in the art to which the disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the application.

Hereinafter, embodiments of the disclosure will be described with reference to the accompanying drawings.

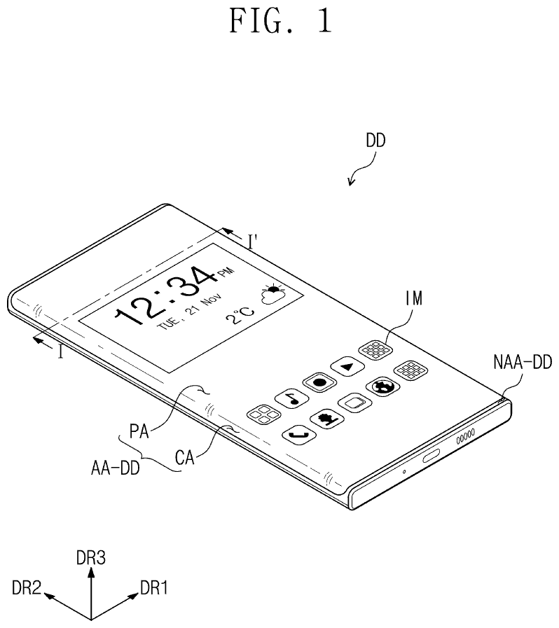

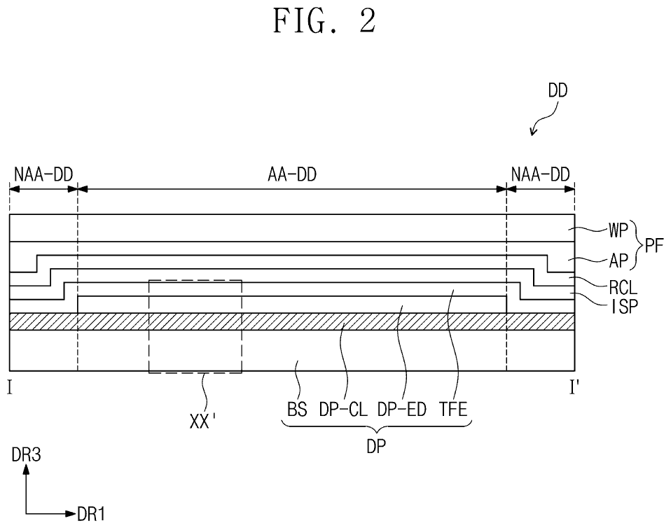

FIG. 1 is a perspective view illustrating an embodiment of a display device DD according to the disclosure. FIG. 2 is a cross-sectional view illustrating a portion corresponding to line I-I′ of FIG. 1. In addition, FIG. 2 may be a cross-sectional view illustrating an embodiment of the display device DD.

The display device DD of an embodiment may be a device activated depending on an electrical signal. In an embodiment, the display device DD may be a mobile phone, a tablet computer, a car navigation unit, a game machine, or a wearable device, for example. However, the disclosure is not limited thereto. FIG. 1 illustrates an example that the display device DD is a mobile phone.

The display device DD may display an image IM through an active area AA-DD. The active area AA-DD may include a flat surface PA defined by a first directional axis DR1 and a second directional axis DR2. The active area AA-DD may further include a curved surface CA bent from at least one side of the flat surface PA defined by the first directional axis DR1 and the second directional axis DR2. In FIG. 1, the display device DD of an embodiment is illustrated as including two curved surfaces CA bent from opposite sides of the flat surface PA defined by the first directional axis DR1 and the second directional axis DR2. However, this is illustrative, and the shape of the active area AA-DD is not limited thereto. In an embodiment, the active area AA-DD may include only the flat surface PA, for example. In an alternative embodiment, the active area AA-DD may further include four curved surfaces CA bent from at least two sides, e.g., four sides of the flat surface PA.

A peripheral area NAA-DD is adjacent to the active area AA-DD. The peripheral area NAA-DD may surround the active area AA-DD. Accordingly, the shape of the active area AA-DD may be substantially defined by the peripheral area NAA-DD. However, this is illustrative, and the peripheral area NAA-DD may be disposed adjacent to only one side of the active area AA-DD, or may be omitted. The display device DD in an embodiment may include active areas having various shapes and is not limited to a particular embodiment.

Although the first to third directional axes DR1 to DR3 are illustrated in FIG. 1 and the following drawings, the directions indicated by the first to third directional axes DR1, DR2, and DR3 described in this specification may be relative concepts and may be changed to other directions. In addition, the directions indicated by the first to third directional axes DR1, DR2, and DR3 may be described as first to third directions, and identical reference numerals may be used to refer to the first to third directions. In this specification, the first directional axis DR1 and the second directional axis DR2 may be orthogonal to each other, and the third directional axis DR3 may correspond to a normal direction to the flat surface PA defined by the first directional axis DR1 and the second directional axis DR2.

The thickness direction of the display device DD may be a direction parallel to the third directional axis DR3 that is the normal direction to the flat surface PA defined by the first directional axis DR1 and the second directional axis DR2. In this specification, front surfaces (or, upper surfaces) and rear surfaces (or, lower surfaces) of members constituting the display device DD may be defined based on the third directional axis DR3. In this specification, an upper side and a lower side may be defined based on the third directional axis DR3. The upper side means a direction close to the active area AA-DD on which the image IM is displayed, and the lower side means a direction away from the active area AA-DD on which the image IM is displayed.

In this specification, when a component is “directly disposed/directly formed” on another component, this means that a third component is not disposed therebetween. That is, when a component is “directly disposed/directly formed” on another component, this means that the component “contacts” the other component.

Referring to FIG. 2, the display device DD of an embodiment may include a display panel DP and a protective member PF disposed on the display panel DP. In addition, the display device DD may further include an input sensing layer ISP disposed between the display panel DP and the protective member PF.

The protective member PF may include an adhesive layer AP and a window WP. The window WP and the input sensing layer ISP may be coupled by the adhesive layer AP. The adhesive layer AP may include a conventional adhesive, such as a pressure sensitive adhesive (“PSA”), an optically clear adhesive (“OCA”), or an optical clear resin (“OCR”), and is not limited to a particular embodiment. Unlike in FIG. 2, the adhesive layer AP may be omitted.

The window WP may include an optically clear insulating material. The window WP may be a glass substrate or a polymer substrate. In an embodiment, the window WP may be a tempered glass substrate, for example. In an alternative embodiment, the window WP may include or consist of polyimide, polyacrylate, polymethylmethacrylate, polycarbonate, polyethylenenaphthalate, polyvinylidene chloride, polyvinylidene difluoride, polystyrene, ethylene vinylalcohol copolymer, or any combinations thereof. However, this is illustrative, and the material included in the window WP is not limited thereto.

Although not illustrated, the protective member PF may further include at least one functional layer (not illustrated) that is provided on the window WP. In an embodiment, the functional layer (not illustrated) may be a hard coating layer or an anti-fingerprint coating layer, for example. However, the disclosure is not limited thereto.

The input sensing layer ISP may be disposed on the display panel DP. The input sensing layer (also referred to as an input sensor layer) ISP may sense an external input applied from the outside. The external input may be a user input. The user input may include various types of external inputs such as a part of a user's body, light, heat, a pen, or pressure.

The input sensing layer ISP may be formed on the display panel DP through a continuous process. In this case, the input sensing layer ISP may be directly disposed on the display panel DP. When the input sensing layer ISP is directly disposed on the display panel DP, it may mean that a third component is not disposed between the input sensing layer ISP and the display panel DP. That is, a separate adhesive member may not be disposed between the input sensing layer ISP and the display panel DP. In an alternative embodiment, the input sensing layer ISP may be coupled with the display panel DP through an adhesive member. The adhesive member may include a conventional adhesive or sticky substance.

In addition, the display device DD may further include an optical layer RCL disposed between the input sensing layer ISP and the protective member PF. The optical layer RCL may be an anti-reflective layer that decreases reflectance by external light. The optical layer RCL may be formed on the input sensing layer ISP through a continuous process. The optical layer RCL may include a polarizer or a color filter layer. When the optical layer RCL includes the color filter layer, the color filter layer may include a plurality of color filters disposed in a predetermined arrangement. In an embodiment, the color filters may be arranged in consideration of the colors of light emitted by pixels included in the display panel DP, for example. In addition, the optical layer RCL may further include a black matrix adjacent to the color filters. In an embodiment, the optical layer RCL may be omitted.

The display panel DP may be a component that substantially generates an image. The display panel DP may be an emissive display panel. In an embodiment, the display panel DP may be an organic light-emitting display panel, an inorganic light-emitting display panel, a quantum-dot display panel, a micro light-emitting diode (“LED”) display panel, or a nano LED display panel, for example. The display panel DP may be also referred to as a display layer. The display panel DP may include a base layer BS, a circuit layer DP-CL, a display element layer DP-ED, and an encapsulation layer TFE.

The base layer BS may be a member that provides a base surface on which the circuit layer DP-CL is disposed. The base layer BS may be a rigid substrate, or may be a flexible substrate that is able to be bent, folded, or rolled. The base layer BS may be a glass substrate, a metal substrate, or a polymer substrate. However, the disclosure is not limited thereto, and the base layer BS may be an inorganic layer, an organic layer, or a composite layer.

The circuit layer DP-CL may be disposed on the base layer BS. The circuit layer DP-CL may include an insulating layer, a semiconductor pattern, a conductive pattern, and a signal line. An insulating layer, a semiconductor layer, and a conductive layer may be formed on the base layer BS by a process such as coating or deposition and may be selectively subjected to patterning by performing a photolithography process a plurality of times. Thereafter, the semiconductor pattern, the conductive pattern, and the signal line included in the circuit layer DP-CL may be formed.

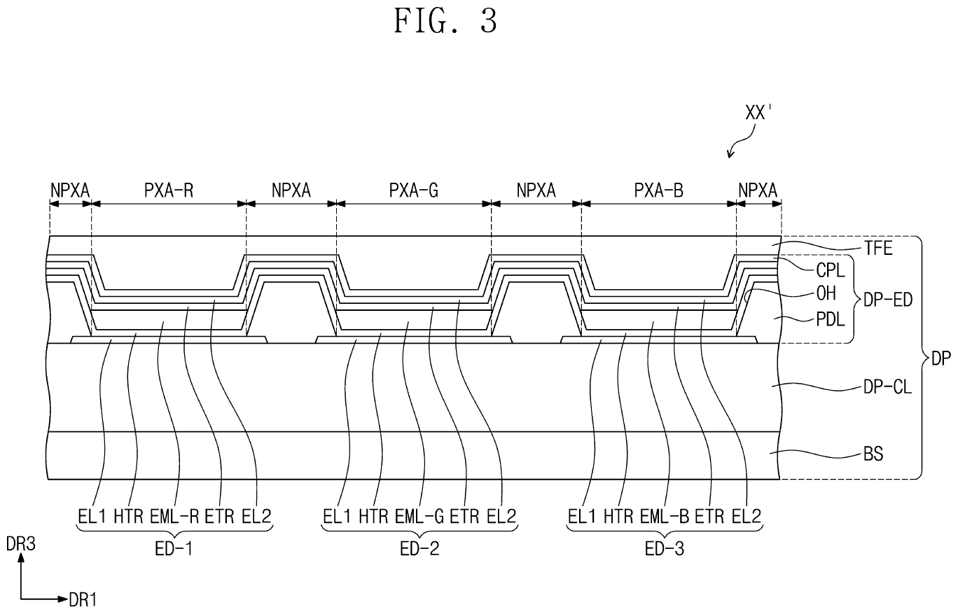

The display element layer DP-ED may be disposed on the circuit layer DP-CL. The display element layer DP-ED may include a pixel defining layer PDL and first to third light-emitting elements ED-1, ED-2, and ED-3 (refer to FIG. 3) that will be described below. In an embodiment, the display element layer DP-ED may include an organic luminescent material, an inorganic luminescent material, an organic-inorganic luminescent material, a quantum dot, a quantum rod, a micro LED, or a nano LED, for example.

The encapsulation layer TFE may be disposed on the display element layer DP-ED. The encapsulation layer TFE may protect the display element layer DP-ED from foreign matter such as moisture, oxygen, and dust particles.

FIG. 3 is an enlarged cross-sectional view illustrating area XX′ in FIG. 2. FIG. 3 may be a cross-sectional view specifically illustrating the display panel DP of FIG. 2.

The base layer BS may include a single-layer structure or a multi-layer structure. In an embodiment, the base layer BS may include a first synthetic resin layer, an intermediate layer having a multi-layer structure or a single-layer structure, and a second synthetic resin layer that are sequentially stacked one above another, for example. The intermediate layer may be also referred to as a base barrier layer. The intermediate layer may include a silicon oxide (SiOₓ) layer and an amorphous silicon (a-Si) layer disposed on the silicon oxide layer, but is not particularly limited thereto. In an embodiment, the intermediate layer may include at least one of a silicon oxide layer, a silicon nitride layer, a silicon oxy nitride layer, or an amorphous silicon layer, for example.

Each of the first and second synthetic resin layers may include a polyimide-based resin. In an alternative embodiment, each of the first and second synthetic resin layers may include at least one of an acrylate-based resin, a methacrylate-based resin, a polyisoprene-based resin, a vinyl-based resin, an epoxy-based resin, a urethane-based resin, a celluose-based resin, a siloxane-based resin, a polyamide-based resin, or a perylene-based resin. In the disclosure, a “˜˜”-based resin used herein may refer to a resin including a “˜˜” functional group.

The circuit layer DP-CL may be disposed on the base layer BS. The circuit layer DP-CL may include a plurality of transistors (not illustrated). Each of the transistors (not illustrated) may include a control electrode, an input electrode, and an output electrode. In an embodiment, the circuit layer DP-CL may include a switching transistor and a driving transistor for driving the light-emitting elements ED-1, ED-2, and ED-3 of the display element layer DP-ED, for example.

The display element layer DP-ED may include the pixel defining layer PDL and the first to third light-emitting elements ED-1, ED-2, and ED-3. Pixel openings OH may be defined in the pixel defining layer PDL. In an embodiment, the pixel defining layer PDL may include an organic light-blocking material or an inorganic light-blocking material that includes a black pigment and a black dye, for example.

The display panel DP may be divided into a non-emissive area NPXA and emissive areas PXA-R, PXA-G, and PXA-B. The emissive areas PXA-R, PXA-G, and PXA-B may be areas from which light generated by the first to third light-emitting elements ED-1, ED-2, and ED-3 is emitted. The emissive areas PXA-R, PXA-G, and PXA-B may be spaced apart from one another when viewed from above the plane.

The emissive areas PXA-R, PXA-G, and PXA-B may be areas divided from one another by the pixel defining layer PDL. The non-emissive area NPXA may be an area between the adjacent emissive areas PXA-R, PXA-G, and PXA-B and may be an area corresponding to the pixel defining layer PDL. In this specification, the emissive areas PXA-R, PXA-G, and PXA-B may correspond to the pixels, respectively. The pixel defining layer PDL may divide the first to third light-emitting elements ED-1, ED-2, and ED-3 from one another. Emissive layers EML-R, EML-G, and EML-B of the first to third light-emitting elements ED-1, ED-2, and ED-3 may be disposed in the pixel openings OH defined in the pixel defining layer PDL and may be divided from one another.

The emissive areas PXA-R, PXA-G, and PXA-B may be divided into a plurality of groups depending on the colors of light generated by the first to third light-emitting elements ED-1, ED-2, and ED-3. Three emissive areas PXA-R, PXA-G, and PXA-B that emit red light, green light, and blue light, respectively, are illustrated in the display panel DP of an embodiment illustrated in FIG. 3. In an embodiment, the display device DD of an embodiment may include the red light-emitting area PXA-R, the green light-emitting area PXA-G, and the blue light-emitting area PXA-B divided from one another, for example.

The first to third light-emitting elements ED-1, ED-2, and ED-3 may be spaced apart from one another in one direction (e.g., the first directional axis (also referred to as a first direction) DR1) perpendicular to the third directional axis (also referred to as a thickness direction) DR3. The first to third light-emitting elements ED-1, ED-2, and ED-3 may emit light in different wavelength ranges. In an embodiment, the first light-emitting element ED-1 may emit red light, the second light-emitting element ED-2 may emit green light, and the third light-emitting element ED-3 may emit blue light. The red light-emitting area PXA-R, the green light-emitting area PXA-G, and the blue light-emitting area PXA-B may correspond to the first light-emitting element ED-1, the second light-emitting element ED-2, and the third light-emitting element ED-3, respectively, for example.

However, the disclosure is not limited thereto, and the first to third light-emitting elements ED-1, ED-2, and ED-3 may emit light in the same wavelength range, or at least one of the first to third light-emitting elements ED-1, ED-2, and ED-3 may emit light in a different wavelength range. In an embodiment, the first to third light-emitting elements ED-1, ED-2, and ED-3 may all emit blue light, for example.

Each of the light-emitting elements ED-1, ED-2, and ED-3 may include a first electrode EL1, a second electrode EL2 disposed over the first electrode EL1, and the emissive layer EML-R, EML-G, or EML-B disposed between the first electrode EL1 and the second electrode EL2. The first electrodes EL1 may be exposed through the pixel openings OH of the pixel defining layer PDL.

In addition, each of the light-emitting elements ED-1, ED-2, and ED-3 may further include a hole transport area HTR and an electron transport area ETR. The hole transport area HTR may be disposed between the first electrode EL1 and the emissive layer EML-R, EML-G, or EML-B. The electron transport area ETR may be disposed between the emissive layer EML-R, EML-G, or EML-B and the second electrode EL2.

FIG. 3 illustrates an embodiment in which the emissive layers EML-R, EML-G, and EML-B of the first to third light-emitting elements ED-1, ED-2, and ED-3 are disposed in the pixel openings OH defined in the pixel defining layer PDL and the hole transport area HTR, the electron transport area ETR, and the second electrode EL2 are provided as common layers in the light-emitting elements ED-1, ED-2, and ED-3. However, the disclosure is not limited thereto, and unlike those illustrated in FIG. 3, in an embodiment, the hole transport area HTR and the electron transport area ETR may be subjected to patterning and provided inside the pixel openings OH defined in the pixel defining layer PDL. In an embodiment, in an embodiment, the hole transport area HTR, the emissive layers EML-R, EML-G, and EML-B, and the electron transport area ETR of the light-emitting elements ED-1, ED-2, and ED-3 may be subjected to patterning by an ink-jet printing method, for example.

The first electrode EL1 may be an anode or a cathode. However, the disclosure is not limited thereto. Furthermore, the first electrode EL1 may be a pixel electrode. The first electrode EL1 may be a transmissive electrode, a transflective electrode, or a reflective electrode. The first electrode EL1 may include at least one selected from the group including Ag, Mg, Cu, Al, Pt, Pd, Au, Ni, Nd, Ir, Cr, Li, Ca, LiF, Mo, Ti, W, In, Sn, and Zn, a compound of two or more elements selected from the group, a combination of two or more elements selected from the group, or oxide thereof.

When the first electrode EL1 is a transmissive electrode, the first electrode EL1 may include transparent metal oxide, e.g., indium tin oxide (“ITO”), indium zinc oxide (“IZO”), zinc oxide (ZnO), or indium tin zinc oxide (“ITZO”). When the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, or a compound or combination thereof (e.g., a combination of Ag and Mg). In an alternative embodiment, the first electrode EL1 may have a multi-layer structure that includes a reflective film or a transflective film including or consisting of the aforementioned materials and a transparent conductive film including or consisting of ITO, IZO, zinc oxide (ZnO), or ITZO. In an embodiment, the first electrode EL1 may have a three-layer structure of ITO/Ag/ITO, for example, but is not limited thereto. Furthermore, the first electrode EL1 may include the aforementioned metallic materials, a combination of two or more metallic materials selected from the aforementioned metallic materials, or oxides of the aforementioned metallic materials, and the disclosure is not limited thereto.

The hole transport area HTR may have a multi-layer structure that has a single layer including or consisting of a single material, a single layer including or consisting of a plurality of different materials, or a plurality of layers including or consisting of a plurality of different materials from each other. The hole transport area HTR may include at least one of a hole injection layer (not illustrated), a hole transport layer (not illustrated), or an electron blocking layer (not illustrated). In addition, the hole transport area HTR may further include a light-emission assisting layer (not illustrated) for compensating for the resonance distance depending on the wavelength of light emitted from the emissive layer EML-R, EML-G, or EML-B.

The hole transport area HTR may include a phthalocyanine compound such as copper phthalocyanine, DNTPD(N¹,N¹′-([1,1′-biphenyl]-4,4′-diyl)bis(N¹-phenyl-N⁴,N⁴-di-m-tolylbenzene-1,4-diamine)), m-MTDATA(4,4′,4″-[tris(3-methylphenyl)phenylamino]triphenylamine), TDATA(4,4′,4″-Tris(N,N-diphenylamino) triphenylamine), 2-TNATA(4,4′,4″-tris[N (2-naphthyl)-N-phenylamino]-triphenylamine), PEDOT/PSS(Poly(3,4-ethylenedioxythiophene)/Poly(4-styrenesulfonate)), PANI/DBSA(Polyaniline/Dodecylbenzenesulfonic acid), PANI/CSA(Polyaniline/Camphor sulfonicacid), PANI/PSS(Polyaniline/Poly(4-styrenesulfonate)), NPB(N,N′-di(naphthalene-1-yl)-N,N′-diphenyl-benzidine), polyether ketone (TPAPEK) including triphenylamine, 4-Isopropyl-4′-methyldiphenyliodonium [Tetrakis(pentafluorophenyl) borate], HATCN(dipyrazino[2,3-f; 2′,3′-h] quinoxaline-2,3,6,7,10,11-hexacarbonitrile), or the like.

In addition, the hole transport area HTR may include a carbazole-based derivative such as N-phenylcarbazole or polyvinylcarbazole, a fluorene-based derivative, TPD(N,N′-bis(3-methylphenyl)-N,N′-diphenyl-[1,1′-biphenyl]-4,4′-diamine), a triphenylamine-based derivative such as TCTA(4,4′,4″-tris(N-carbazolyl)triphenylamine), TAPC(4,4′-Cyclohexylidene bis[N,N-bis(4-methylphenyl)benzenamine]), HMTPD(4,4′-Bis[N,N′-(3-tolyl)amino]-3,3′-dimethylbiphenyl), CzSi(9-(4-tert-Butylphenyl)-3,6-bis(triphenylsilyl)-9H-carbazole), CCP(9-phenyl-9H-3,9′-bicarbazole), mCP(1,3-Bis(N-carbazolyl)benzene), or mDCP(1,3-bis(1,8-dimethyl-9H-carbazol-9-yl)benzene).

The emissive layer EML-R, EML-G, or EML-B may have a multi-layer structure that has a single layer including or consisting of a single material, a single layer including or consisting of a plurality of different materials, or a plurality of layers including or consisting of a plurality of different materials from each other. The emissive layer EML-R, EML-G, or EML-B may include an anthracene derivative, a pyrene derivative, a fluoranthene derivative, a chrysene derivative, a dihydrobenzanthracene derivative, or a triphenylene derivative.

In an embodiment, the emissive layer EML-R, EML-G, or EML-B may include one host and one dopant, for example. In an alternative embodiment, the emissive layer EML-R, EML-G, or EML-B may include two or more hosts and two or more dopants.

The emissive layer EML-B of the third light-emitting element ED-3 that emits blue light may emit thermally activated delayed fluorescence (TADF) or phosphorescence. The emissive layer EML-B of the third light-emitting element ED-3 may include a thermally activated delayed fluorescent material and/or a phosphorescent material. The third light-emitting element ED-3 including the thermally activated delayed fluorescent material and/or the phosphorescent material may exhibit excellent luminous efficiency.

The emissive layer EML-R, EML-G, or EML-B may include a styryl derivative (e.g., 1,4-bis[2-(3-N-ethylcarbazolyl)vinyl]benzene(BCzVB), 4-(di-p-tolylamino)-4′-[(di-p-tolylamino)styryl]stilbene(DPAVB), N-(4-((E)-2-(6-((E)-4-(diphenylamino)styryl)naphthalen-2-yl)vinyl)phenyl)-N-phenylbenzenamine(N-BDAVBi)), or 4,4′-bis[2-(4-(N,N-diphenylamino)phenyl)vinyl]biphenyl(DPAVBi)), perylene and a derivative thereof (e.g., 2,5,8,11-Tetra-t-butylperylene(TBP)), or pyrene and a derivative thereof (e.g., 1,1-dipyrene, 1,4-dipyrenylbenzene, 1,4-Bis(N, N-Diphenylamino) pyrene) as a well-known dopant material.

The emissive layer EML-R, EML-G, or EML-B may include a well-known phosphorescent dopant material. In an embodiment, a metal complex including iridium (Ir), platinum (Pt), osmium (Os), gold (Au), titanium (Ti), zirconium (Zr), hafnium (Hf), europium (Eu), terbium (Tb), or thulium (Tm) may be used as a phosphorescent dopant, for example. Specifically, FIrpic(iridium(III) bis(4,6-difluorophenylpyridinato-N,C2′)picolinate), FIr6(Bis(2,4-difluorophenylpyridinato)-tetrakis(1-pyrazolyl)borate iridium(III)), or PtOEP(platinum octaethyl porphyrin) may be used as a phosphorescent dopant. However, the disclosure is not limited thereto.

The electron transport area ETR may include at least one of a hole blocking layer (not illustrated), an electron transport layer (not illustrated), or an electron injection layer (not illustrated). The electron transport area ETR may have a multi-layer structure that has a single layer including or consisting of a single material, a single layer including or consisting of a plurality of different materials, or a plurality of layers including or consisting of a plurality of different materials from each other.

The electron transport area ETR may include an anthracene-based compound. However, without being limited thereto, the electron transport area ETR may include, e.g., Alq₃(Tris(8-hydroxyquinolinato)aluminum), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, TPBi(1,3,5-Tri(1-phenyl-1H-benzo[d]imidazol-2-yl)benzene), BCP(2,9-Dimethyl-4,7-diphenyl-1,10-phenanthroline), Bphen(4,7-Diphenyl-1,10-phenanthroline), TAZ(3-(4-Biphenylyl)-4-phenyl-5-tert-butylphenyl-1,2,4-triazole), NTAZ(4-(Naphthalen-1-yl)-3,5-diphenyl-4H-1,2,4-triazole), tBu-PBD(2-(4-Biphenylyl)-5-(4-tert-butylphenyl)-1,3,4-oxadiazole), BAlq(Bis(2-methyl-8-quinolinolato-N1,O8)-(1,1′-Biphenyl-4-olato)aluminum), Bebq₂(berylliumbis(benzoquinolin-10-olate)), ADN(9,10-di(naphthalene-2-yl)anthracene), BmPyPhB(1,3-Bis[3,5-di(pyridin-3-yl)phenyl]benzene), or any combinations thereof.

In addition, the electron transport area ETR may include a metal halide such as LiF, NaCl, CsF, RbCl, RbI, CuI, or KI, a lanthanide metal such as Yb, or a co-deposition material of the metal halide and the lanthanide metal. In an embodiment, the electron transport area ETR may include KI:Yb, RbI:Yb, or LiF:Yb as a co-deposition material. Metal oxide such as Li₂O or BaO, Liq(8-hydroxyl-Lithium quinolate), or the like may be used for the electron transport area ETR, but the disclosure is not limited thereto. The electron transport area ETR may include or consist of a combination of an electron transport material and an insulating organometallic salt. The organometallic salt may be a material having an energy band gap of about 4 electronvolts (eV) or more. Specifically, the organometallic salt may include metal acetate, metal benzoate, metal acetoacetate, metal acetylacetonate, or metal stearate, for example.

The second electrode EL2 may be a common electrode. The second electrode EL2 may be a cathode or an anode, but the disclosure is not limited thereto. In an embodiment, when the first electrode EL1 is an anode, the second electrode EL2 may be a cathode, and when the first electrode EL1 is a cathode, the second electrode EL2 may be an anode, for example. The second electrode EL2 may include at least one selected from the group including Ag, Mg, Cu, Al, Pt, Pd, Au, Ni, Nd, Ir, Cr, Li, Ca, LiF, Mo, Ti, W, In, Sn, and Zn, a compound of two or more elements selected from the group, a combination of two or more elements selected from the group, or oxide thereof.

The light-emitting elements ED-1, ED-2, and ED-3 may further include a capping layer CPL disposed on the second electrode EL2. The capping layer CPL may be an organic layer or an inorganic layer. In an embodiment, when the capping layer CPL includes an inorganic material, the inorganic material may include an alkali metal compound (e.g., LiF), an alkaline earth metal compound (e.g., MgF₂), SiON, SiNₓ, SiO_{y}, or the like, for example. In an embodiment, when the capping layer CPL includes an organic material, the organic material may include α-NPD, NPB, TPD, m-MTDATA, Alq₃, CuPc, TPD15(N4,N4,N4′,N4′-tetra (biphenyl-4-yl) biphenyl-4,4′-diamine), or TCTA(4,4′,4″-Tris(carbazol-9-yl)triphenylamine), or may include an epoxy resin or acrylate such as methacrylate, for example.

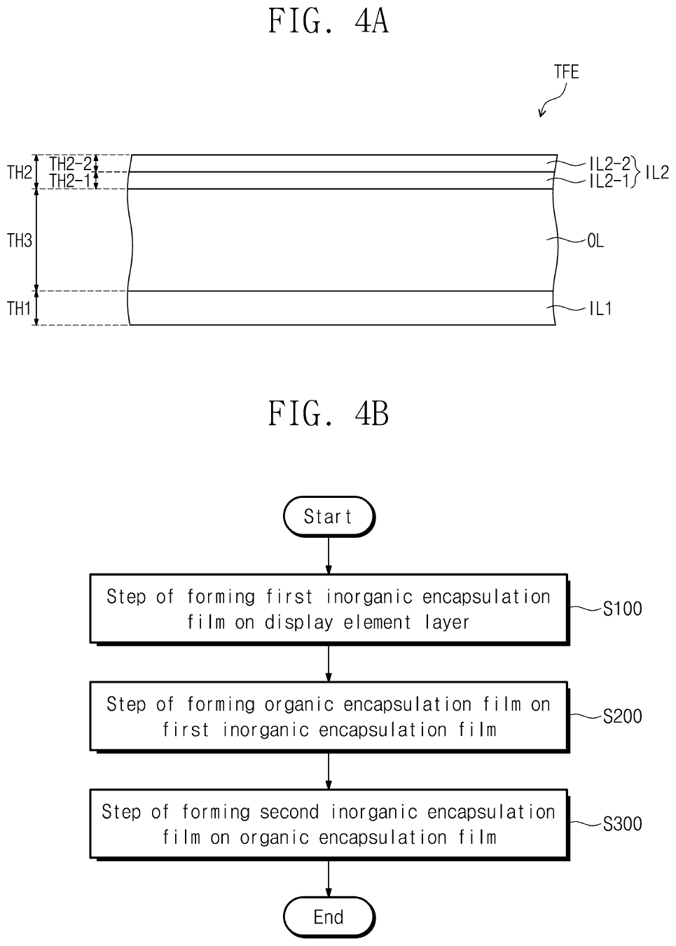

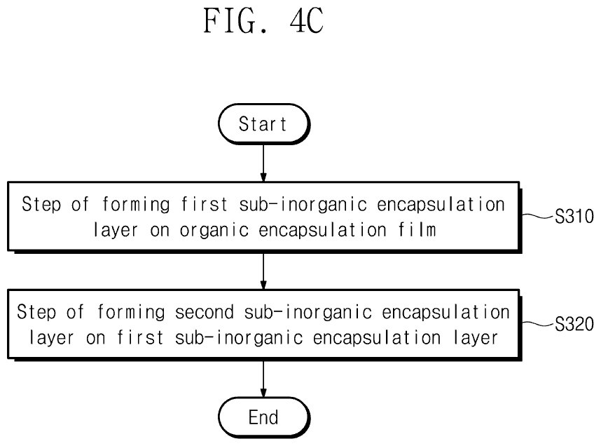

In an embodiment, the encapsulation layer TFE may cover the display element layer DP-ED. The encapsulation layer TFE may be a thin film encapsulation layer. The encapsulation layer TFE will be described below in detail with reference to FIG. 4A.

FIG. 4A is a cross-sectional view illustrating an embodiment of a portion of the display panel DP (refer to FIG. 3) according to the disclosure. FIG. 4A is a cross-sectional view illustrating the encapsulation layer TFE.

Referring to FIGS. 3 and 4A, the encapsulation layer TFE in an embodiment may include a first inorganic encapsulation film IL1, an organic encapsulation film OL disposed on the first inorganic encapsulation film IL1, and a second inorganic encapsulation film IL2 disposed on the organic encapsulation film OL.

Each of the first inorganic encapsulation film IL1 and the second inorganic encapsulation film IL2 may protect the display element layer DP-ED from moisture and/or oxygen. Each of the first inorganic encapsulation film IL1 and the second inorganic encapsulation film IL2 may include at least one of silicon nitride, silicon oxy nitride, silicon oxide, titanium oxide, or aluminum oxide.

In this embodiment, the sum of the thickness TH1 of the first inorganic encapsulation film IL1 and the thickness TH2 of the second inorganic encapsulation film IL2 may be 1 micrometer or less. In this embodiment, the thickness TH2 of the second inorganic encapsulation film IL2 may be 0.5 micrometer or less.

In this embodiment, the second inorganic encapsulation film IL2 may include a first sub-inorganic encapsulation layer IL2-1 and a second sub-inorganic encapsulation layer IL2-2 that are sequentially stacked. The first sub-inorganic encapsulation layer IL2-1 and the second sub-inorganic encapsulation layer IL2-2 may have different densities from each other. The second sub-inorganic encapsulation layer IL2-2 may have a higher density than a density of the first sub-inorganic encapsulation layer IL2-1. In this embodiment, the first sub-inorganic encapsulation layer IL2-1 may be also referred to as a low-density layer, and the second sub-inorganic encapsulation layer IL2-2 may be also referred to as a high-density layer.

The first sub-inorganic encapsulation layer IL2-1 and the second sub-inorganic encapsulation layer IL2-2 include the same material as each other. In an embodiment, both the first sub-inorganic encapsulation layer IL2-1 and the second sub-inorganic encapsulation layer IL2-2 may include silicon nitride SiNₓ, for example.

In this embodiment, the thickness TH2 of the second inorganic encapsulation film IL2 may correspond to the sum of the thickness TH2-1 of the first sub-inorganic encapsulation layer IL2-1 and the thickness TH2-2 of the second sub-inorganic encapsulation layer IL2-2.

In this embodiment, the first sub-inorganic encapsulation layer IL2-1 may contact the organic encapsulation film OL. The first sub-inorganic encapsulation layer IL2-1 or the low-density layer may cover particles remaining on the organic encapsulation film OL. Accordingly, a relatively flat upper surface may be provided for a component (e.g., the second sub-inorganic encapsulation layer IL2-2) disposed on the first sub-inorganic encapsulation layer IL2-1. The second sub-inorganic encapsulation layer IL2-2 may be disposed at the outermost position of the encapsulation layer TFE. The second sub-inorganic encapsulation layer IL2-2 or the high-density layer may reduce the water vapor transmission rate (“WVTR”) of the encapsulation layer TFE.

In an embodiment, the thickness TH1 of the first inorganic encapsulation film IL1 may also be 0.5 micrometer or less. That is, both the thickness TH1 of the first inorganic encapsulation film IL1 and the thickness TH2 of the second inorganic encapsulation film IL2 may be 0.5 micrometer or less. However, as long as the sum of the thickness TH1 of the first inorganic encapsulation film IL1 and the thickness TH2 of the second inorganic encapsulation film IL2 is 1 micrometer or less, the thickness TH1 of the first inorganic encapsulation film IL1 is not limited thereto.

The organic encapsulation film OL may protect the display element layer DP-ED from foreign matter such as dust particles. The organic encapsulation film OL may include an acrylic compound, an epoxy compound, or the like. The organic encapsulation film OL may include an organic material capable of photopolymerization, but is not particularly limited. In an embodiment, the organic encapsulation film OL may have a thickness TH3 of 5 micrometers to 10 micrometeres.

In an embodiment, the encapsulation layer TFE may have a WVTR of 1.5×10⁻⁴ grams per square meter per 24 hours (g/m² day) or less. Preferably, the encapsulation layer TFE may have a WVTR of 10⁻⁵ g/m² day to 10⁻⁴ g/m² day.

Hereinafter, characteristics evaluation results of display panels in embodiments of the disclosure will be described with reference to FIGS. 3 and 4A described above and the following embodiments and comparative examples. In addition, the embodiments below are for a better understanding of the disclosure, and the scope of the disclosure is not limited thereto.

In a display panel of Comparative Example 1, a first inorganic encapsulation film is a single inorganic film having a thickness of 0.8 micrometers, a second inorganic encapsulation film is a single inorganic film having a thickness of 0.7 micrometers, and an organic encapsulation film is an organic film having a thickness of 8 micrometers. In a display panel of Embodiment 1, a first inorganic encapsulation film is a single inorganic film having a thickness of 0.6 micrometers, a second inorganic encapsulation film has a thickness of 0.4 micrometers and includes a low-density layer and a high-density layer that are sequentially stacked, and an organic encapsulation film is an organic film having a thickness of 8 micrometers. The high-density layer of Embodiment 1 has a higher density than a density of the single inorganic film of the second inorganic encapsulation film of Comparative Example 1. The display panel of Comparative Example 1 and the display panel of Embodiment 1 have the structure of the display panel DP described above with reference to FIG. 3.

Table 1 below shows the measured light efficiencies and WVTRs of the display panels of Comparative Example 1 and Embodiment 1. In the case of the light efficiencies, the evaluation results when white light is provided from the front and the evaluation results when white light is provided at an angle of 45° with respect to the front are shown. Furthermore, in the case of the light efficiencies, the luminances (in terms of candela/square meter (cd/m²)) depending on currents are measured, and the luminance values in Embodiment 1 represent relative values based on the luminance values in Comparative Example 1, with the luminance values in Comparative Example 1 being set to 100%.

TABLE 1

| | Light Efficiency | Light Efficiency | WVTR(g/m2 |
|---|---|---|---|
| | (%, White, Front) | (%, White, 45°) | day) |
| Comparative | 100 | 100 | 1.4E−04 |
| Example 1 | | | |
| Embodiment 1 | 102.3 | 102.2 | 1.5E−04 |

Referring to table 1, it may be seen that since the encapsulation layer of Embodiment 1 has a smaller thickness than the encapsulation layer of Comparative Example 1, the display panel of Embodiment 1 exhibits excellent light efficiency when compared to the display panel of Comparative Example 1.

In addition, it may be seen that the display panel of Embodiment 1 has a smaller level of WVTR when compared to the display panel of Comparative Example 1. As the thickness of the second inorganic encapsulation film is increased, the WVTR may be decreased. However, since the second inorganic encapsulation film of Embodiment 1 includes the high-density film, the display panel of Embodiment 1 has a relatively low level of WVTR even though the second inorganic encapsulation film is relatively thin. To provide a thick inorganic encapsulation film, a longer tact time period may be desired, and production efficiency may be reduced. In contrast, according to the disclosure, a thin inorganic encapsulation film may be provided, and thus an encapsulation layer having relatively high barrier characteristics while improving mass productivity and reducing costs and a display device including the encapsulation layer may be provided.

FIGS. 4B and 4C are flowcharts illustrating an embodiment of a method of manufacturing the display device according to the disclosure.

Referring to FIGS. 3, 4A, and 4B, the display device manufacturing method in an embodiment of the disclosure may include an operation S100 of forming the first inorganic encapsulation film IL1 on the display element layer DP-ED, an operation S200 of forming the organic encapsulation film OL on the first inorganic encapsulation film IL1, and an operation S300 of forming the second inorganic encapsulation film IL2 on the organic encapsulation film OL. Accordingly, the encapsulation layer TFE that seals the display element layer DP-ED may be formed.

The operation S100 of forming the first inorganic encapsulation film IL1 and the operation S300 of forming the second inorganic encapsulation film IL2 may be performed through chemical vapor deposition (“CVD”). In an embodiment, the operation S100 of forming the first inorganic encapsulation film IL1 and the operation S300 of forming the second inorganic encapsulation film IL2 may be performed through plasma enhanced CVD (“PECVD”), for example. The operation S200 of forming the organic encapsulation film OL may be performed through an ink-jet process.

Referring to FIGS. 3 and 4A to 4C, in an embodiment of the disclosure, the operation S300 of forming the second inorganic encapsulation film IL2 may include an operation S310 of depositing the first sub-inorganic encapsulation layer IL2-1 on the organic encapsulation film OL and an operation S320 of depositing the second sub-inorganic encapsulation layer IL2-2 on the first sub-inorganic encapsulation layer IL2-1. The operation S310 of depositing the first sub-inorganic encapsulation layer IL2-1 and the operation S320 of depositing the second sub-inorganic encapsulation layer IL2-2 may each be performed through CVD.

In the operation S310 of depositing the first sub-inorganic encapsulation layer IL2-1 and the operation S320 of depositing the second sub-inorganic encapsulation layer IL2-2, the same material may be deposited. In an embodiment, in the operation S310 of depositing the first sub-inorganic encapsulation layer IL2-1 and the operation S320 of depositing the second sub-inorganic encapsulation layer IL2-2, silicon nitride (SiNₓ) may be deposited. The operation S310 of depositing the first sub-inorganic encapsulation layer IL2-1 and the operation S320 of depositing the second sub-inorganic encapsulation layer IL2-2 may be performed in the same chamber.

The operation S310 of depositing the first sub-inorganic encapsulation layer IL2-1 and the operation S320 of depositing the second sub-inorganic encapsulation layer IL2-2 may be controlled and performed with different process parameters. More specifically, the process parameters in the respective steps may be controlled such that the second sub-inorganic encapsulation layer IL2-2 has a higher density than a density of the first sub-inorganic encapsulation layer IL2-1. In an embodiment, the deposition rate in the operation S310 of depositing the first sub-inorganic encapsulation layer IL2-1 and the deposition rate in the operation S320 of depositing the second sub-inorganic encapsulation layer IL2-2 may be set to be different from each other, for example.

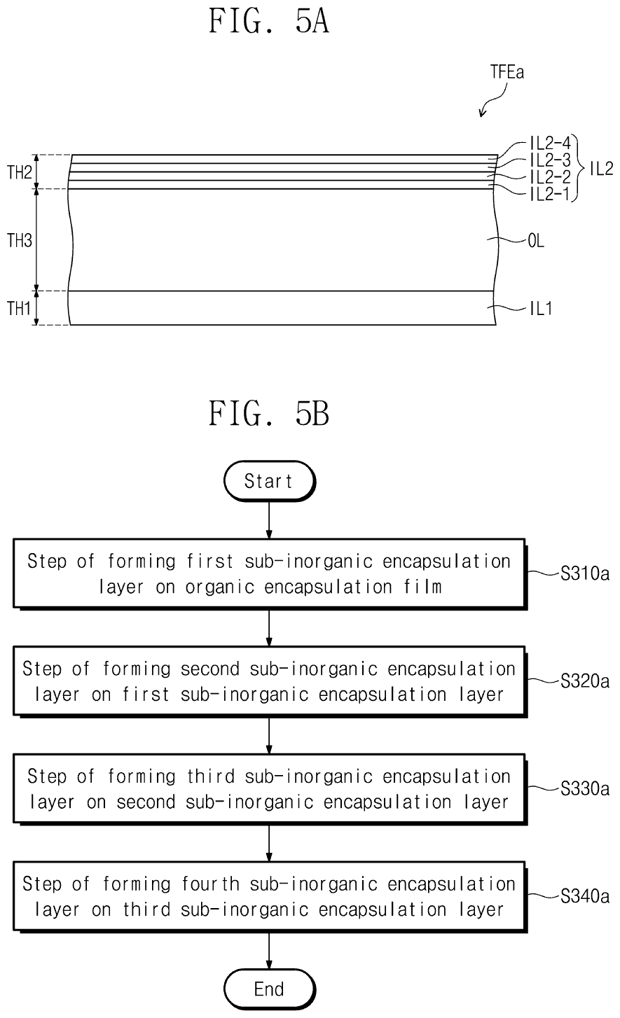

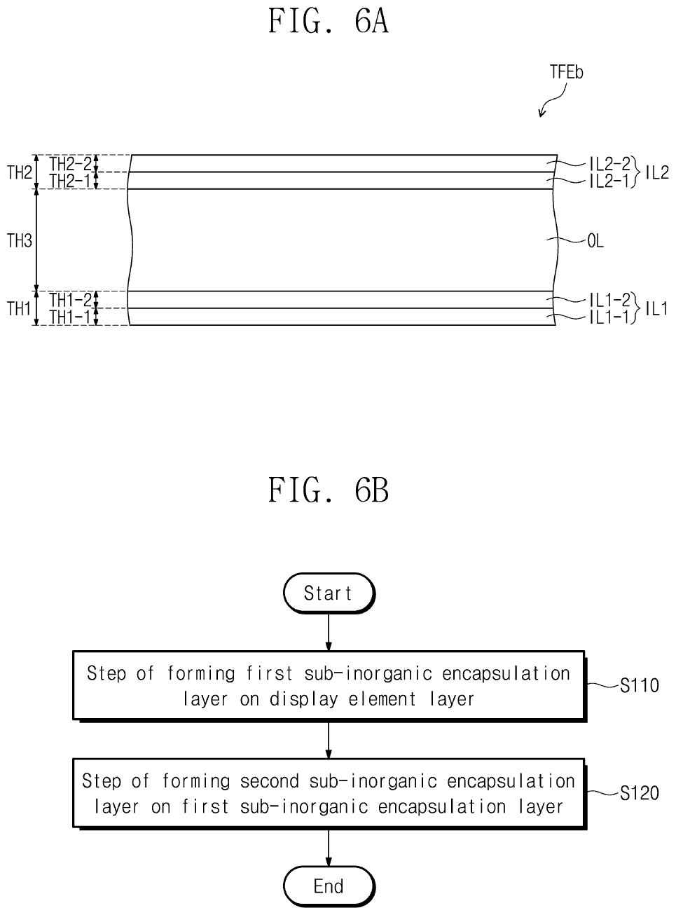

FIG. 5A is a cross-sectional view illustrating an embodiment of a portion of the display panel DP (refer to FIG. 3) according to the disclosure. FIG. 5A is a cross-sectional view illustrating an encapsulation layer TFEa. The encapsulation layer TFEa may include a first inorganic encapsulation film IL1, an organic encapsulation film OL, and a second inorganic encapsulation film IL2. Components identical or similar to the components described with reference to FIGS. 4A to 4C will be assigned with identical or similar reference numerals, and repetitive descriptions will be omitted.

Referring to FIG. 5A, the second inorganic encapsulation film IL2 in an embodiment may include a first sub-inorganic encapsulation layer IL2-1, a second sub-inorganic encapsulation layer IL2-2, a third sub-inorganic encapsulation layer IL2-3, and a fourth sub-inorganic encapsulation layer IL2-4 that are sequentially stacked. Among the first to fourth sub-inorganic encapsulation layers IL2-1, IL2-2, IL2-3, and IL2-4, sub-inorganic encapsulation layers contacting each other may have different densities from each other. In this embodiment, the first sub-inorganic encapsulation layer IL2-1 may be also referred to as a first low-density layer, the second sub-inorganic encapsulation layer IL2-2 may be also referred to as a first high-density layer, the third sub-inorganic encapsulation layer IL2-3 may be also referred to as a second low-density layer, and the fourth sub-inorganic encapsulation layer IL2-4 may be also referred to as a second high-density layer. That is, in this embodiment, the second inorganic encapsulation film IL2 may have a structure in which low-density layers and high-density layers are alternately stacked. Although FIG. 5 illustrates an example that a low-density layer and a high-density layer are repeated twice, the number of times that a low-density layer and a high-density layer are repeated is not limited thereto.

In this embodiment, the first sub-inorganic encapsulation layer IL2-1 or the first low-density layer may contact the organic encapsulation film OL, and the fourth sub-inorganic encapsulation layer IL2-4 or the second high-density layer may be disposed at the outermost position of the encapsulation layer TFEa. That is, the second inorganic encapsulation film IL2 may be provided such that a low-density layer contacts the organic encapsulation film OL and a high-density layer is disposed at the outermost position of the encapsulation layer TFEa.

The first to fourth sub-inorganic encapsulation layers IL2-1, IL2-2, IL2-3, and IL2-4 may include the same material as each other. In an embodiment, the first to fourth sub-inorganic encapsulation layers IL2-1, IL2-2, IL2-3, and IL2-4 may all include silicon nitride SiNₓ, for example.

The sum of the thickness TH1 of the first inorganic encapsulation film IL1 and the thickness TH2 of the second inorganic encapsulation film IL2 may be 1 micrometer or less. In this embodiment, the thickness TH2 of the second inorganic encapsulation film IL2 may be 0.5 micrometer or less. The thickness TH2 of the second inorganic encapsulation film IL2 may correspond to the sum of the thickness of the first sub-inorganic encapsulation layer IL2-1, the thickness of the second sub-inorganic encapsulation layer IL2-2, the thickness of the third sub-inorganic encapsulation layer IL2-3, and the thickness of the fourth sub-inorganic encapsulation layer IL2-4.

FIG. 5B is a flowchart illustrating an embodiment of a method of manufacturing the display device according to the disclosure.

Referring to FIGS. 3, 4B, 5A, and 5B, in an embodiment of the disclosure, the operation S300 of forming the second inorganic encapsulation film IL2 may include an operation S310a of depositing the first sub-inorganic encapsulation layer IL2-1 on the organic encapsulation film OL, an operation S320a of depositing the second sub-inorganic encapsulation layer IL2-2 on the first sub-inorganic encapsulation layer IL2-1, an operation S330a of forming the third sub-inorganic encapsulation layer IL2-3 on the second sub-inorganic encapsulation layer IL2-2, and an operation S340a of forming the fourth sub-inorganic encapsulation layer IL2-4 on the third sub-inorganic encapsulation layer IL2-3. The operation S310a of depositing the first sub-inorganic encapsulation layer IL2-1, the operation S320a of depositing the second sub-inorganic encapsulation layer IL2-2, the operation S330a of depositing the third sub-inorganic encapsulation layer IL2-3, and the operation S340a of depositing the fourth sub-inorganic encapsulation layer IL2-4 may each be performed through CVD.

In the operation S310a of depositing the first sub-inorganic encapsulation layer IL2-1, the operation S320a of depositing the second sub-inorganic encapsulation layer IL2-2, the operation S330a of depositing the third sub-inorganic encapsulation layer IL2-3, and the operation S340a of depositing the fourth sub-inorganic encapsulation layer IL2-4, the same material (e.g., silicon nitride (SiNₓ)) may be deposited. The operation S310a of depositing the first sub-inorganic encapsulation layer IL2-1, the operation S320a of depositing the second sub-inorganic encapsulation layer IL2-2, the operation S330a of depositing the third sub-inorganic encapsulation layer IL2-3, and the operation S340a of depositing the fourth sub-inorganic encapsulation layer IL2-4 may be performed in the same chamber.

The operation S310a of depositing the first sub-inorganic encapsulation layer IL2-1 and the operation S320a of depositing the second sub-inorganic encapsulation layer IL2-2 may be controlled and performed with different process parameters. The operation S320a of depositing the second sub-inorganic encapsulation layer IL2-2 and the operation S330a of depositing the third sub-inorganic encapsulation layer IL2-3 may be controlled and performed with different process parameters. The operation S330a of depositing the third sub-inorganic encapsulation layer IL2-3 and the operation S340a of depositing the fourth sub-inorganic encapsulation layer IL2-4 may be controlled and performed with different process parameters. Accordingly, the second sub-inorganic encapsulation layer IL2-2 may have a higher density than a density of the first sub-inorganic encapsulation layer IL2-1 and the third sub-inorganic encapsulation layer IL2-3. The fourth sub-inorganic encapsulation layer IL2-4 may have a higher density than a density of the third sub-inorganic encapsulation layer IL2-3.

FIG. 6A is a cross-sectional view illustrating an embodiment of a portion of the display panel DP (refer to FIG. 3) according to the disclosure. FIG. 6A is a cross-sectional view illustrating an encapsulation layer TFEb. The encapsulation layer TFEb may include a first inorganic encapsulation film IL1, an organic encapsulation film OL, and a second inorganic encapsulation film IL2. Components identical/similar to the components described with reference to FIGS. 4A to 5B will be assigned with identical/similar reference numerals, and repetitive descriptions will be omitted.

Referring to FIG. 6A, the second inorganic encapsulation film IL2 in an embodiment may include a first sub-inorganic encapsulation layer IL2-1 and a second sub-inorganic encapsulation layer IL2-2 that are sequentially stacked. The second sub-inorganic encapsulation layer IL2-2 may have a higher density than a density of the first sub-inorganic encapsulation layer IL2-1. In this embodiment, the first sub-inorganic encapsulation layer IL2-1 may be also referred to as a first low-density layer, and the second sub-inorganic encapsulation layer IL2-2 may be also referred to as a first high-density layer.

The first inorganic encapsulation film IL1 in an embodiment may include a first sub-inorganic encapsulation layer IL1-1 and a second sub-inorganic encapsulation layer IL1-2 that are sequentially stacked. The first sub-inorganic encapsulation layer IL1-1 and the second sub-inorganic encapsulation layer IL1-2 include the same material as each other. The first sub-inorganic encapsulation layer IL1-1 and the second sub-inorganic encapsulation layer IL1-2 may have different densities from each other. In an embodiment, the second sub-inorganic encapsulation layer IL1-2 may have a higher density than a density of the first sub-inorganic encapsulation layer IL1-1. In this case, the first sub-inorganic encapsulation layer IL1-1 may be also referred to as a second low-density layer, and the second sub-inorganic encapsulation layer IL1-2 may be also referred to as a second high-density layer, for example.

The disclosure, however, is not limited thereto, and the first sub-inorganic encapsulation layer IL1-1 may have a higher density than a density of the second sub-inorganic encapsulation layer IL1-2. In this case, the first sub-inorganic encapsulation layer IL1-1 may be also referred to as a second high-density layer, and the second sub-inorganic encapsulation layer IL1-2 may be also referred to as a second low-density layer.

The sum of the thickness TH1 of the first inorganic encapsulation film IL1 and the thickness TH2 of the second inorganic encapsulation film IL2 may be 1 micrometer or less. In this embodiment, the thickness TH2 of the second inorganic encapsulation film IL2 may be 0.5 micrometer or less. The thickness TH2 of the second inorganic encapsulation film IL2 may correspond to the sum of the thickness TH2-1 of the first sub-inorganic encapsulation layer IL2-1 and the thickness TH2-2 of the second sub-inorganic encapsulation layer IL2-2. In an embodiment, the thickness TH1 of the first inorganic encapsulation film IL1 may be 0.5 micrometer or less. The thickness TH1 of the first inorganic encapsulation film IL1 may correspond to the sum of the thickness TH1-1 of the first sub-inorganic encapsulation layer IL1-1 and the thickness TH1-2 of the second sub-inorganic encapsulation layer IL1-2.

FIG. 6B is a flowchart illustrating an embodiment of a method of manufacturing the display device according to the disclosure.

Referring to FIGS. 3 4B, 6A, and 6B, in an embodiment of the disclosure, the operation S100 of forming the first inorganic encapsulation film IL1 may include an operation S110 of depositing the first sub-inorganic encapsulation layer IL1-1 on the display element layer DP-ED and an operation S120 of depositing the second sub-inorganic encapsulation layer IL1-2 on the first sub-inorganic encapsulation layer IL1-1. The operation S110 of depositing the first sub-inorganic encapsulation layer IL1-1 and the operation S120 of depositing the second sub-inorganic encapsulation layer IL1-2 may each be performed through CVD.

In the operation S110 of depositing the first sub-inorganic encapsulation layer IL1-1 and the operation S120 of depositing the second sub-inorganic encapsulation layer IL1-2, the same material may be deposited. In an embodiment, in the operation S110 of depositing the first sub-inorganic encapsulation layer IL1-1 and the operation S120 of depositing the second sub-inorganic encapsulation layer IL1-2, silicon nitride (SiNₓ) may be deposited. The operation S110 of depositing the first sub-inorganic encapsulation layer IL1-1 and the operation S120 of depositing the second sub-inorganic encapsulation layer IL1-2 may be performed in the same chamber.

The operation S110 of depositing the first sub-inorganic encapsulation layer IL1-1 and the operation S120 of depositing the second sub-inorganic encapsulation layer IL1-2 may be controlled and performed with different process parameters. More specifically, the process parameters in the respective steps may be controlled such that the first sub-inorganic encapsulation layer IL1-1 and the second sub-inorganic encapsulation layer IL1-2 have different densities from each other. In an embodiment, the deposition rate in the operation S110 of depositing the first sub-inorganic encapsulation layer IL1-1 and the deposition rate in the operation S120 of depositing the second sub-inorganic encapsulation layer IL1-2 may be set to be different from each other, for example.

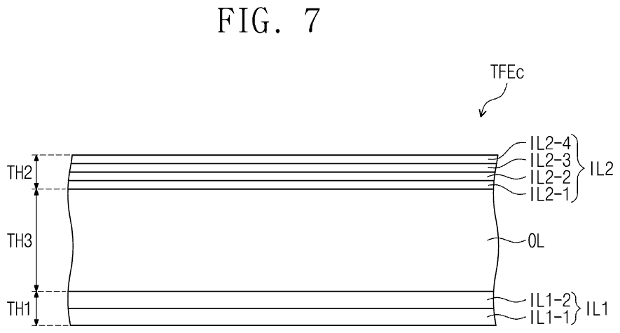

FIG. 7 is a cross-sectional view illustrating an embodiment of a portion of the display panel DP (refer to FIG. 3) according to the disclosure. FIG. 7 is a cross-sectional view illustrating an encapsulation layer TFEc. The encapsulation layer TFEc may include a first inorganic encapsulation film IL1, an organic encapsulation film OL, and a second inorganic encapsulation film IL2. Components identical/similar to the components described with reference to FIGS. 4A to 6B will be assigned with identical/similar reference numerals, and repetitive descriptions will be omitted.

Referring to FIG. 7, the second inorganic encapsulation film IL2 in an embodiment may include a first sub-inorganic encapsulation layer IL2-1, a second sub-inorganic encapsulation layer IL2-2, a third sub-inorganic encapsulation layer IL2-3, and a fourth sub-inorganic encapsulation layer IL2-4 that are sequentially stacked. Among the first to fourth sub-inorganic encapsulation layers IL2-1, IL2-2, IL2-3, and IL2-4, sub-inorganic encapsulation layers contacting each other may have different densities from each other. In this embodiment, the first to fourth sub-inorganic encapsulation layers IL2-1, IL2-2, IL2-3, and IL2-4 may be also referred to as a first-first low-density layer, a first-first high-density layer, a first-second low-density layer, and a first-second high-density layer, respectively.

The first inorganic encapsulation film IL1 in an embodiment may include a first sub-inorganic encapsulation layer IL1-1 and a second sub-inorganic encapsulation layer IL1-2 that are sequentially stacked. The first sub-inorganic encapsulation layer IL1-1 and the second sub-inorganic encapsulation layer IL1-2 may have different densities from each other. In an embodiment, the first and second sub-inorganic encapsulation layers IL1-1 and IL1-2 may be also referred to as a second low-density layer and a second high-density layer, respectively, for example. In an alternative embodiment, the first and second sub-inorganic encapsulation layers IL1-1 and IL1-2 may be also referred to as a second high-density layer and a second low-density layer, respectively.

The sum of the thickness TH1 of the first inorganic encapsulation film IL1 and the thickness TH2 of the second inorganic encapsulation film IL2 may be 1 micrometer or less. In this embodiment, the thickness TH2 of the second inorganic encapsulation film IL2 may be 0.5 micrometer or less. The thickness TH2 of the second inorganic encapsulation film IL2 may correspond to the sum of the thickness of the first sub-inorganic encapsulation layer IL2-1, the thickness of the second sub-inorganic encapsulation layer IL2-2, the thickness of the third sub-inorganic encapsulation layer IL2-3, and the thickness of the fourth sub-inorganic encapsulation layer IL2-4.

In an embodiment of the disclosure, the thickness TH1 of the first inorganic encapsulation film IL1 may be 0.5 micrometer or less. The thickness TH1 of the first inorganic encapsulation film IL1 may correspond to the sum of the thickness of the first sub-inorganic encapsulation layer IL1-1 and the thickness of the second sub-inorganic encapsulation layer IL1-2. However, as long as the sum of the thickness TH1 of the first inorganic encapsulation film IL1 and the thickness TH2 of the second inorganic encapsulation film IL2 is 1 micrometer or less, the thickness TH1 of the first inorganic encapsulation film IL1 is not limited thereto.

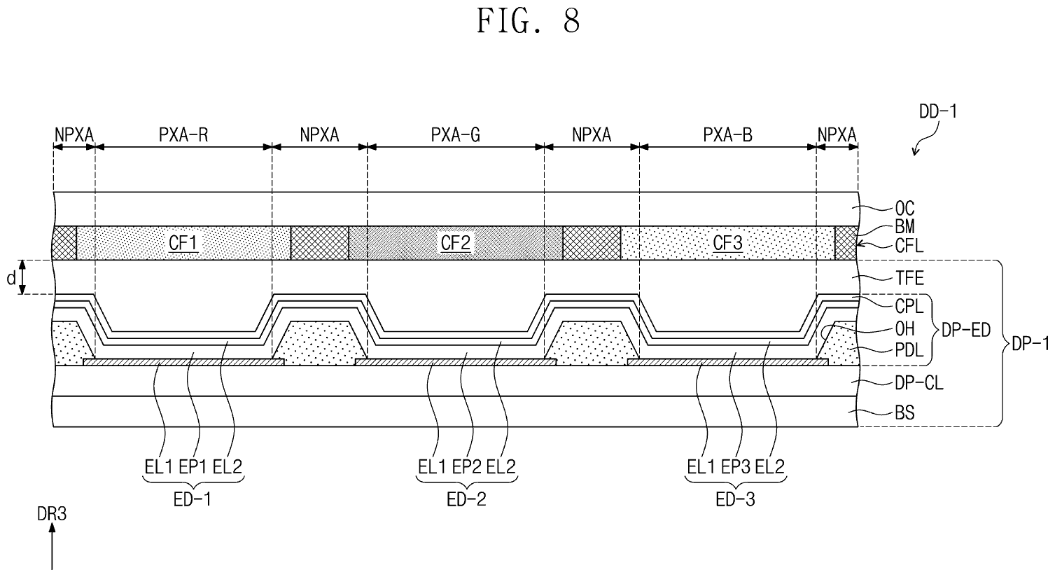

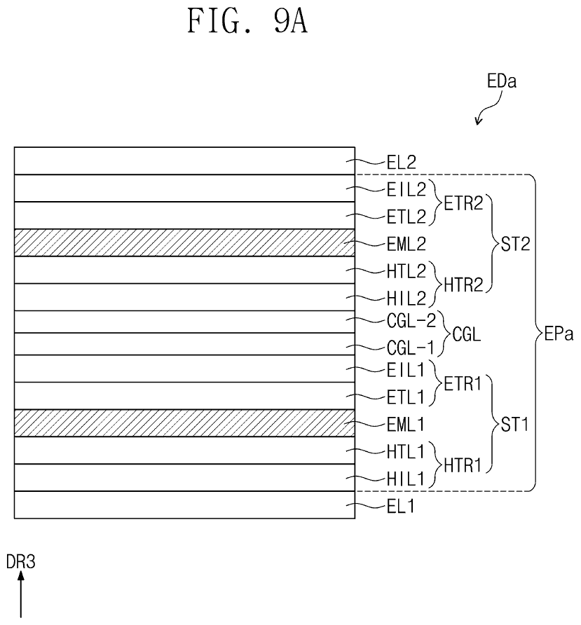

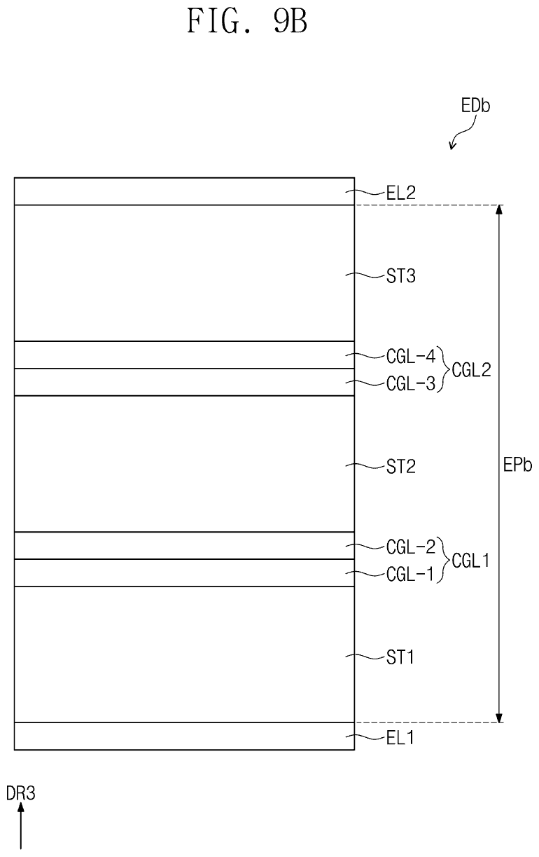

FIG. 8 is a cross-sectional view illustrating an embodiment of a display device DD-1 according to the disclosure. FIGS. 9A and 9B are enlarged cross-sectional views of an embodiment of portions of light-emitting elements EDa and EDb according to the disclosure.

Referring to FIGS. 8 to 9B, the display device DD-1 may include a display panel DP-1, and the display panel DP-1 may include a base layer BS, a circuit layer DP-CL disposed on the base layer BS, a display element layer DP-ED disposed on the circuit layer DP-CL, and an encapsulation layer TFE disposed on the display element layer DP-ED. In addition, the display device DD-1 in an embodiment may further include a color filter layer CFL and a planarization layer OC that are disposed on the encapsulation layer TFE. The color filter layer CFL may be a component corresponding to the optical layer RCL in FIG. 2.

In an embodiment, the base layer BS may be a silicon wafer. The circuit layer DP-CL may be formed by performing a CMOS process on the silicon wafer. In this case, the circuit layer DP-CL may include a fine semiconductor pattern and a conductive pattern and may provide the display panel DP-1 capable of easily implementing relatively high resolution.

Each of light-emitting elements ED-1, ED-2, and ED-3 according to this embodiment may include a first electrode EL1, a second electrode EL2 disposed over the first electrode EL1, and a light-emitting part EP1, EP2, or EP3 disposed between the first electrode EL1 and the second electrode EL2. The first to third light-emitting elements ED-1, ED-2, and ED-3 may include the first to third light-emitting parts EP1, EP2, and EP3, respectively. Each of the light-emitting elements EDa and EDb of FIGS. 9A and 9B may correspond to one of the first to third light-emitting elements ED-1, ED-2, and ED-3 of FIG. 8. Each of light-emitting parts EPa and EPb of FIGS. 9A and 9B may correspond to one of the first to third light-emitting parts EP1, EP2, and EP3 of FIG. 8.

Referring to FIG. 9A, the light-emitting part EPa in an embodiment of the disclosure may include a first light-emitting stack ST1, a charge generation layer CGL, and a second light-emitting stack ST2 that are sequentially stacked in the third directional axis (also referred to as a third direction) DR3. The light-emitting element EDa may be a light-emitting element having a tandem structure that includes the plurality of light-emitting stacks ST1 and ST2.

The first light-emitting stack ST1 may include a first emissive layer EML1, and a first hole control layer HTR1 and a first electron control layer ETR1 disposed with the first emissive layer EML1 therebetween.

The first hole control layer HTR1 may include at least one of a first hole injection layer HIL1 or a first hole transport layer HTL1. The first hole transport layer HTL1 may include at least one of a first hole buffer layer or a first electron blocking layer.

The first electron control layer ETR1 may include at least one of a first electron injection layer EIL1 or a first electron transport layer ETL1. The first electron control layer ETR1 may further include a first hole blocking layer.

The second light-emitting stack ST2 may include a second emissive layer EML2, and a second hole control layer HTR2 and a second electron control layer ETR2 disposed with the second emissive layer EML2 therebetween.

The second hole control layer HTR2 may include at least one of a second hole injection layer HIL2 or a second hole transport layer HTL2. The second electron control layer ETR2 may include at least one of a second electron injection layer EIL2 or a second electron transport layer ETL2. The description of the first hole control layer HTR1 and the first electron control layer ETR1 may be identically applied to description of the second hole control layer HTR2 and the second electron control layer ETR2.

In an embodiment, light emitted from the light-emitting stacks ST1 and ST2 may be light in the same wavelength range. In an embodiment, light emitted from the light-emitting stacks ST1 and ST2 may be blue light, for example. However, the disclosure is not limited thereto, and the light-emitting stacks ST1 and ST2 may emit light in different wavelength ranges. In an embodiment, at least one of the light-emitting stacks ST1 and ST2 may emit blue light, and the rest may emit green light, for example. The light-emitting element EDa including the light-emitting stacks ST1 and ST2 that emit light in different wavelength ranges may emit white light.

The charge generation layer CGL may be disposed between the first light-emitting stack ST1 and the second light-emitting stack ST2. When a voltage is applied, the charge generation layer CGL may generate charges (electrons and holes) by forming a complex through an oxidation-reduction reaction. The charge generation layer CGL may provide the generated charges to the light-emitting stacks ST1 and ST2. The charge generation layer CGL may double the current efficiencies generated in the light-emitting stacks ST1 and ST2 and may serve to balance the charges between the first light-emitting stack ST1 and the second light-emitting stack ST2.

More specifically, the charge generation layer CGL may have a layer structure in which a lower charge generation layer CGL-1 and an upper charge generation layer CGL-2 are bonded to each other. The lower charge generation layer CGL-1 may be an n-type charge generation layer that is disposed adjacent to the first light-emitting stack ST1 and that provides electrons to the first light-emitting stack ST1. The lower charge generation layer CGL-1 may include an aryl amine-based organic compound.

The upper charge generation layer CGL-2 may be a p-type charge generation layer that is disposed adjacent to the second light-emitting stack ST2 and that provides holes to the second light-emitting stack ST2. The upper charge generation layer CGL-2 may include a charge generation compound including or consisting of metal, oxide, carbide, or fluoride of the metal, or any combinations thereof.

A buffer layer may be additionally disposed between the lower charge generation layer CGL-1 and the upper charge generation layer CGL-2.

According to this embodiment, the first light-emitting stack ST1, the charge generation layer CGL, and the second light-emitting stack ST2 may be commonly formed in a plurality of pixels using an open mask. However, without being limited thereto, at least one of the first and second hole control layers HTR1 and HTR2, the first and second emissive layers EML1 and EML2, and the first and second electron control layers ETR1 and ETR2 may be formed by being subjected to patterning through a mask. In an embodiment, the first and second emissive layers EML1 and EML2 may be disposed in areas corresponding to pixel openings OH (refer to FIG. 8), for example. That is, the first and second emissive layers EML1 and EML2 may be separately formed in pixels, respectively.

Referring to FIG. 9B, the light-emitting part EPb in an embodiment of the disclosure may include a first light-emitting stack ST1, a first charge generation layer CGL1, a second light-emitting stack ST2, a second charge generation layer CGL2, and a third light-emitting stack ST3. That is, in this embodiment, the light-emitting part EPb may include three light-emitting stacks ST1, ST2, and ST3 and two charge generation layers CGL1 and CGL2 disposed between the adjacent light-emitting stacks ST1, ST2, and ST3. Components identical/similar to the components described with reference to FIG. 9A will be assigned with identical/similar reference numerals, and repetitive descriptions will be omitted.

The third light-emitting stack ST3 may have a structure similar to those of the first and second light-emitting stacks ST1 and ST2 described above with reference to FIG. 9A. The third light-emitting stack ST3 may include a third hole control layer, a third emissive layer, and a third electron control layer that are sequentially stacked on the second charge generation layer CGL2 in the third direction DR3.

In addition, each of the first and second charge generation layers CGL1 and CGL2 may have a structure similar to that of the charge generation layer CGL described above with reference to FIG. 9A. The first charge generation layer CGL1 may have a layer structure in which a first lower charge generation layer CGL-1 and a first upper charge generation layer CGL-2 are bonded to each other, and the second charge generation layer CGL2 may have a layer structure in which a second lower charge generation layer CGL-3 and a second upper charge generation layer CGL-4 are bonded to each other.

The number of light-emitting stacks ST1, ST2, and ST3 and the number of charge generation layers CGL1 and CGL2 are not limited to those illustrated in FIGS. 9A and 9B, and four or more light-emitting stacks and three or more charge generation layers disposed therebetween may be included.

Referring back to FIG. 8, the descriptions of the encapsulation layers TFE, TFEa, TFEb, and TFEc described with reference to FIGS. 4A to 7 may be identically applied to the encapsulation layer TFE. The color filter layer CFL may be disposed on the encapsulation layer TFE. The color filter layer CFL may include a first color filter CF1 corresponding to a red light-emitting area (also referred to as a first pixel area) PXA-R, a second color filter CF2 corresponding to a green light-emitting area (also referred to as a second pixel area) PXA-G, and a third color filter CF3 corresponding to a blue light-emitting area (also referred to as a third pixel area) PXA-B. The color filter layer CFL may further include a light-blocking part BM. The light-blocking part BM may be disposed in a non-emissive area (also referred to as a non-pixel area) NPXA to have a narrower width than the non-pixel area NPXA. However, without being limited thereto, the light-blocking part BM may be disposed to correspond to the non-pixel area NPXA. The light-blocking part BM may be a black matrix. The light-blocking part BM may include or consist of an organic light-blocking material or an inorganic light-blocking material that includes or consists of a black pigment or a black dye. The light-blocking part BM may prevent light leakage and may divide the color filters CF1, CF2, and CF3 from one another. In the disclosure, the expression “one area/portion corresponds to another area/portion” used herein means that the areas/portions overlap each other and is not limited to having the same area.

Each of the first to third color filters CF1, CF2, and CF3 may include a photosensitive polymer resin and a colorant. In this specification, the colorant includes a pigment and a dye. A red colorant may include a red pigment and a red dye, a green colorant may include a green pigment and a green dye, and a blue colorant may include a blue pigment and a blue dye.

In an embodiment, the first color filter CF1 may include a red pigment or a red dye, the second color filter CF2 may include a blue pigment or a blue dye, and the third color filter CF3 may include a green pigment or a green dye, for example. Light that is provided from the light-emitting part EP and that passes through the first color filter CF1 may provide red light outside the display panel DP-1, light that is provided from the light-emitting part EP and that passes through the second color filter CF2 may provide blue light outside the display panel DP-1, and light that is provided from the light-emitting part EP and that passes through the third color filter CF3 may provide green light outside the display panel DP-1.

The planarization layer OC may be disposed on the color filter layer CFL. The planarization layer OC may cover the first to third color filters CF1, CF2, and CF3. The planarization layer OC may include an organic material. The organic material may be transparent and may include, e.g., an acrylic resin. The planarization layer OC may provide a flat upper surface. In another embodiment, the planarization layer OC may be omitted.

Referring to FIGS. 4A and 8, table 2 below shows the measured light efficiencies of display panels of Comparative Example 2 and Embodiment 2. In the display panel of Comparative Example 2, a first inorganic encapsulation film is a single inorganic film having a thickness of 0.8 micrometers, a second inorganic encapsulation film is a single inorganic film having a thickness of 0.7 micrometers, and an organic encapsulation film is an organic film having a thickness of 8 micrometers. In the display panel of Embodiment 2, a first inorganic encapsulation film is a single inorganic film having a thickness of 0.6 micrometers, a second inorganic encapsulation film has a thickness of 0.4 micrometers and includes a low-density layer and a high-density layer that are sequentially stacked, and an organic encapsulation film is an organic film having a thickness of 8 micrometers. The high-density layer of Embodiment 2 has a higher density than a density of the single inorganic film of the second inorganic encapsulation film of Comparative Example 2. The display panel of Comparative Example 2 and the display panel of Embodiment 2 have the structure of the display panel DP-1 described above with reference to FIG. 8.

In the case of the light efficiencies, the evaluation results when white light is provided from the front are shown. Furthermore, in the case of the light efficiencies, the luminances (cd/A) depending on currents are measured, and the luminance value in Embodiment 2 represents a relative values based on the luminance value in Comparative Example 2, with the luminance value in Comparative Example 2 being set to 100%.

TABLE 2

| | Light Efficiency |
|---|---|
| | (%, White, Front) |
| Comparative Example 2 | 100 |
| Embodiment 2 | 106.2 |

Referring to table 2, it may be seen that since the encapsulation layer of Embodiment 2 has a smaller thickness than the encapsulation layer of Comparative Example 2, the display panel of Embodiment 2 exhibits excellent light efficiency when compared to the display panel of Comparative Example 2. The distance d between the display element layer DP-ED and the color filter layer CFL may be shorter in the display panel of Embodiment 2 than in the display panel of Comparative Example 2. Accordingly, the display panel of Embodiment 2 may prevent and/or reduce light reaching an adjacent emissive area. Thus, color mixing may be prevented so that light efficiency may be improved.

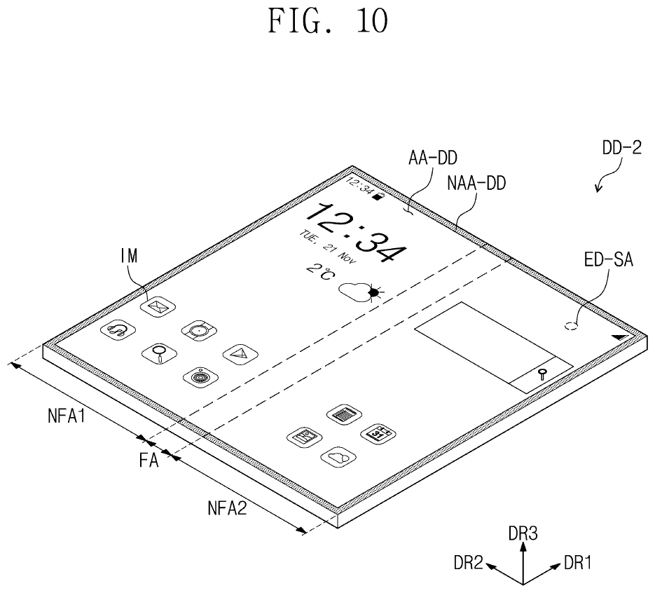

FIG. 10 is a perspective view illustrating an embodiment of a display device DD-2 according to the disclosure. Components identical/similar to the components described with reference to FIG. 1 will be assigned with identical/similar reference numerals, and repetitive descriptions will be omitted.

Referring to FIG. 10, the display device DD-2 according to this embodiment may include a folding area FA and a plurality of non-folding areas NFA1 and NFA2. The non-folding areas NFA1 and NFA2 may include the first non-folding area NFA1 and the second non-folding area NFA2. The folding area FA may be disposed between the first non-folding area NFA1 and the second non-folding area NFA2. The first non-folding area NFA1, the folding area FA, and the second non-folding area NFA2 may be arranged in the second directional axis (also referred to as a second direction) DR2. The folding area FA may be also referred to as a foldable area, and the first and second non-folding areas NFA1 and NFA2 may be also referred to as first and second non-foldable areas.

Although one folding area FA and two non-folding areas NFA1 and NFA2 are illustrated in an embodiment, the number of folding areas FA and the number of non-folding areas NFA1 and NFA2 are not limited thereto. In an embodiment, the display device DD-2 may include more than two non-folding areas and a plurality of folding areas disposed between the non-folding areas, for example.

A sensor area ED-SA may be defined in an active area AA-DD of the display device DD-2. Although one sensor area ED-SA is illustrated as an example in FIG. 10, the number of sensor areas ED-SA is not limited thereto. The sensor area ED-SA may be a portion of the active area AA-DD. The display device DD-2 may display an image through the senor area ED-SA. However, the disclosure is not limited thereto. In an embodiment, a portion of a display panel that corresponds to the sensor area ED-SA may be removed, and the sensor area ED-SA may not display an image, for example.

An electronic module may be disposed in an area overlapping the sensor area ED-SA. The electronic module may receive an external input transferred through the sensor area ED-SA, or may provide an output through the sensor area ED-SA. In an embodiment, the electronic module may be a camera module, a sensor (e.g., a proximity sensor) that measures a distance, a sensor that recognizes a part of a user's body (e.g., a fingerprint, an iris, or a face), or a relatively small lamp that outputs light, for example, but is not particularly limited thereto. Hereinafter, it will be exemplified that the electronic module overlapping the sensor area ED-SA is a camera module.

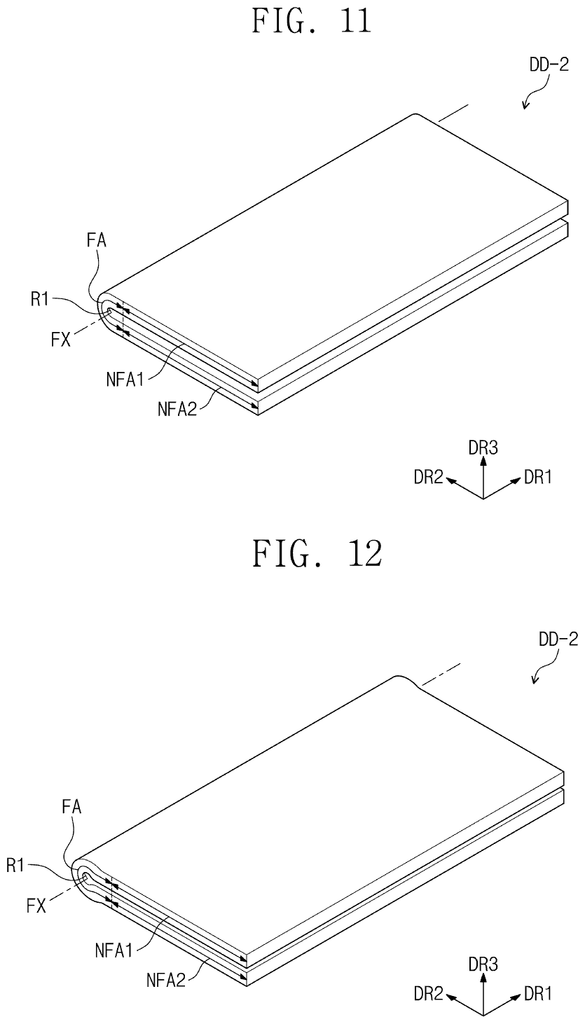

FIGS. 11 and 12 are perspective views of an embodiment of the folded display device DD-2 according to the disclosure. In FIGS. 11 and 12, a folded state of the display device DD-2 illustrated in FIG. 10 is illustrated.

Referring to FIGS. 11 and 12, the display device DD-2 may be a foldable display device DD-2 that is folded or unfolded. In an embodiment, the folding area FA may be bent about a virtual folding axis FX parallel to the first direction DR1, and the display device DD-2 may be folded accordingly, for example. The folding axis FX may be defined as a long axis parallel to the long sides of the display device DD-2.

When the display device DD-2 is folded, the first non-folding area NFA1 and the second non-folding area NFA2 may face each other, and the display device DD-2 may be folded in an in-folding manner such that the display surface is not exposed to the outside. However, embodiments of the disclosure are not limited thereto. In an embodiment, the display device DD-2 may be folded about the folding axis FX in an out-folding manner such that the display surface is exposed to the outside, for example.

The folding area FA may be bent to have a radius of curvature R1. As illustrated in FIG. 11, the distance between the first non-folding area NFA1 and the second non-folding area NFA2 may be substantially the same as twice the radius of curvature R1 (e.g., the diameter). In this case, the display device DD-2 may be folded in the shape of “U”.

However, without being limited thereto, as illustrated in FIG. 12, the distance between the first non-folding area NFA1 and the second non-folding area NFA2 may be smaller than twice the radius of curvature R1. In this case, the display device DD-2 may be folded in a dumbbell shape.

The display device DD-2 of this embodiment may include one of the encapsulation layers TFE, TFEa, TFEb, and TFEc described above with reference to FIGS. 4A to 7. According to this embodiment, since the foldable display device DD-2 includes one of the thinner encapsulation layers TFE, TFEa, TFEb, and TFEc (refer to FIGS. 4A to 7), bending characteristics may be improved, and thus folding reliability may be improved. At the same time, the display device may include an encapsulation layer that has a relatively low WVTR while improving mass productivity and reducing costs, and the display device with improved light efficiency may be provided.

According to the disclosure, the display device may include the encapsulation layer having a relatively small thickness and a relatively low WVTR. Accordingly, the display device may have high barrier characteristics while improving mass productivity and reducing costs.

According to the disclosure, since the encapsulation layer has a relatively small thickness, the display device with improved light efficiency may be provided. In implementing a high-resolution display device, color mixing may be prevented as the distance between the display element layer and the color filter layer is decreased. Accordingly, light efficiency may be improved. In implementing a foldable display device, bending characteristics may be improved, and thus folding reliability may be improved.

While the disclosure has been described with reference to embodiments thereof, it will be apparent to those of ordinary skill in the art that various changes and modifications may be made thereto without departing from the spirit and scope of the disclosure as set forth in the following claims.

What is claimed is:

1. A display device comprising:
a display panel including:
a display element layer including:
a pixel defining layer defining a pixel opening therein; and
a light-emitting element; and
an encapsulation layer disposed on the display element layer, the encapsulation layer including:
a first inorganic encapsulation film;
an organic encapsulation film disposed on the first inorganic encapsulation film; and
a second inorganic encapsulation film disposed on the organic encapsulation film, the second inorganic encapsulation film including:
a first sub-inorganic encapsulation layer; and
a second sub-inorganic encapsulation layer disposed on the first sub-inorganic encapsulation layer, the second sub-inorganic encapsulation layer including a material identical to a material of the first sub-inorganic encapsulation layer,
wherein a density of the first sub-inorganic encapsulation layer and a density of the second sub-inorganic encapsulation layer are different from each other, and
wherein a sum of a thickness of the first inorganic encapsulation film and a thickness of the second inorganic encapsulation film is 1 micrometer or less.

2. The display device of claim 1, wherein the density of the second sub-inorganic encapsulation layer is higher than the density of the first sub-inorganic encapsulation layer.

3. The display device of claim 1, wherein the first sub-inorganic encapsulation layer and the second sub-inorganic encapsulation layer include silicon nitride.

4. The display device of claim 1, wherein the thickness of the second inorganic encapsulation film is 0.5 micrometer or less.

5. The display device of claim 1, wherein the thickness of the first inorganic encapsulation film is 0.5 micrometer or less.

6. The display device of claim 1, wherein the second inorganic encapsulation film further includes:
a third sub-inorganic encapsulation layer disposed on the second sub-inorganic encapsulation layer; and
a fourth sub-inorganic encapsulation layer disposed on the third sub-inorganic encapsulation layer,
wherein a material of each of the third sub-inorganic encapsulation layer and the fourth sub-inorganic encapsulation layer is identical to the material of the first sub-inorganic encapsulation layer,
wherein the density of the second sub-inorganic encapsulation layer and a density of the third sub-inorganic encapsulation layer are different from each other, and
wherein the density of the third sub-inorganic encapsulation layer and a density of the fourth sub-inorganic encapsulation layer are different from each other.

7. The display device of claim 1, wherein the first inorganic encapsulation film includes:
a first sub-inorganic encapsulation layer; and
a second sub-inorganic encapsulation layer disposed on the first sub-inorganic encapsulation layer of the first inorganic encapsulation film, wherein the second sub-inorganic encapsulation layer of the first inorganic encapsulation film includes a material identical to a material of the first sub-inorganic encapsulation layer of the first inorganic encapsulation film, and
wherein a density of the first sub-inorganic encapsulation layer of the first inorganic encapsulation film and a density of the second sub-inorganic encapsulation layer of the first inorganic encapsulation film are different from each other.

8. The display device of claim 1, wherein the encapsulation layer has a water vapor transmission rate of less than or equal to 1.5×10⁻⁴ grams per square meter per 24 hours.

9. The display device of claim 1, wherein the light-emitting element includes:
a first electrode;
an emissive layer disposed on the first electrode; and
a second electrode disposed on the emissive layer.

10. The display device of claim 1, further includes an active area configured to display an image, and
wherein the active area includes a flat area and at least one curved area bent from the flat area.

11. The display device of claim 1, further comprising:
a base layer including a silicon wafer disposed under the display element layer; and
a color filter layer disposed on the encapsulation layer.

12. The display device of claim 11, wherein the light-emitting element includes:
a first electrode;
a light-emitting part including a first light-emitting stack disposed on the first electrode, a charge generation layer disposed on the first light-emitting stack, and a second light-emitting stack disposed on the charge generation layer; and
a second electrode disposed on the light-emitting part.

13. The display device of claim 1, further includes a folding area folded about a virtual axis configured to extend in one direction, and a first non-folding area and a second non-folding area disposed with the folding area therebetween.

14. A method for manufacturing a display device, the method comprising:
forming a first inorganic encapsulation film on a display element layer including a pixel defining layer having a pixel opening defined therein and a light-emitting element;
forming an organic encapsulation film on the first inorganic encapsulation film; and
forming a second inorganic encapsulation film on the organic encapsulation film, the forming the second inorganic encapsulation film including:
depositing a first sub-inorganic encapsulation layer; and
depositing a second sub-inorganic encapsulation layer on the first sub-inorganic encapsulation layer,
wherein a material of the first sub-inorganic encapsulation layer and a material of the second sub-inorganic encapsulation layer are identical to each other,
wherein a density of the first sub-inorganic encapsulation layer and a density of the second sub-inorganic encapsulation layer are different from each other, and
wherein a sum of a thickness of the first inorganic encapsulation film and a thickness of the second inorganic encapsulation film is 1 micrometer or less.

15. The method of claim 14, wherein the depositing the first sub-inorganic encapsulation layer and the depositing the second sub-inorganic encapsulation layer are controlled with different process parameters.

16. The method of claim 14, wherein the forming the second inorganic encapsulation film further includes:
depositing a third sub-inorganic encapsulation layer on the second sub-inorganic encapsulation layer; and
depositing a fourth sub-inorganic encapsulation layer on the third sub-inorganic encapsulation layer,
wherein a material of each of the third sub-inorganic encapsulation layer and the fourth sub-inorganic encapsulation layer is identical to the material of the first sub-inorganic encapsulation layer,
wherein the density of the second sub-inorganic encapsulation layer and a density of the third sub-inorganic encapsulation layer are different from each other, and
wherein the density of the third sub-inorganic encapsulation layer and a density of the fourth sub-inorganic encapsulation layer are different from each other.

17. The method of claim 14, wherein the forming the first inorganic encapsulation film includes:
depositing a first sub-inorganic encapsulation layer of the first inorganic encapsulation film on the display element layer; and
depositing a second sub-inorganic encapsulation layer of the first inorganic encapsulation film on the first sub-inorganic encapsulation layer of the first inorganic encapsulation film, and
wherein a material of the first sub-inorganic encapsulation layer of the first inorganic encapsulation film and a material of the second sub-inorganic encapsulation layer of the first inorganic encapsulation film are identical to each other, and
wherein a density of the first sub-inorganic encapsulation layer of the first inorganic encapsulation film and a density of the second sub-inorganic encapsulation layer of the first inorganic encapsulation film are different from each other.

18. The method of claim 14, wherein the first sub-inorganic encapsulation layer and the second sub-inorganic encapsulation layer include silicon nitride.

19. The method of claim 14, wherein the second inorganic encapsulation film has a thickness of 0.5 micrometer or less.

20. The method of claim 14, wherein the density of the second sub-inorganic encapsulation layer is higher than the density of the first sub-inorganic encapsulation layer.
